(19) United States
(12) Patent Application Publication
(10) Pub. No.: US 2025/0323046 A1
(43) Pub. Date: Oct. 16, 2025

(54) MOLYBDENUM DEPOSITION

(71) Applicant: Lam Research Corporation, Fremont, CA (US)

(72) Inventors: Jeong-Seok NA, San Jose, CA (US); Yao-Tsung HSIEH, San Jose, CA (US); Chiukin Steven LAI, Sunnyvale, CA (US); Patrick A. VAN CLEEMPUT, Castle Rock, WA (US)

(21) Appl. No.: 19/217,348

(22) Filed: May 23, 2025

Related U.S. Application Data
(63) Continuation of application No. 17/639,846, filed on Mar. 2, 2022, now Pat. No. 12,334,351.
(60) Provisional application No. 62/895,407, filed on Sep. 3, 2019.

(51) Int. Cl. H01L 21/285; C23C 16/02; C23C 16/04; C23C 16/08; C23C 16/455; H01L 21/768

(52) U.S. Cl. CPC H01L 21/28568; C23C 16/0245; C23C 16/045; C23C 16/08; C23C 16/45553; H01L 21/76879

(57) ABSTRACT

Provided are methods of filling patterned features with molybdenum (Mo). The methods involve selective deposition of Mo films on bottom metal-containing surfaces of a feature including dielectric sidewalls. The selective growth of Mo on the bottom surface allows bottom-up growth and high quality, void-free fill. Also provided are related apparatus.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Deposition of metals is an integral part of many semiconductor fabrication processes. These materials may be used for horizontal interconnects, vias between adjacent metal layers, and contacts between metal layers and devices. However, as devices shrink and more complex patterning schemes are utilized in the industry, uniform deposition of low resistivity metal films becomes a challenge.

### SUMMARY

Provided are methods of filling patterned features with molybdenum (Mo). The methods involve selective deposition of Mo films on bottom metal-containing surfaces of a feature including dielectric sidewalls. The selective growth of Mo on the bottom surface allows bottom-up growth and high quality, void-free fill. Also provided are related apparatus.

One aspect of the disclosure relates to a method that includes providing a substrate including a feature having a feature bottom and feature sidewalls, where the feature bottom includes a metal-containing surface and the feature sidewalls include oxide or nitride surfaces and performing multiple cycles of an atomic layer deposition (ALD) process to selectively deposit a molybdenum (Mo) film on the metal-containing surface relative to the oxide or nitride surfaces, where the ALD process includes exposing the feature to alternate pulses of molybdenum-containing oxyhalide precursor and a reducing agent at a first substrate temperature.

In some embodiments, the method also includes, prior to performing the multiple cycles of the ALD deposition process, exposing the metal-containing surface to a hydrogen-containing plasma. In some embodiments, the reducing agent is thermal hydrogen (H₂). In some embodiments, the reducing agent is provided in a plasma generated from hydrogen (H₂). In some embodiments, the partial pressure of the reducing agent is at least 10 torr. In some embodiments, the molybdenum-containing precursor is a molybdenum oxychloride. In some embodiments, the first temperature is no more than 600° C. In some embodiments, the first temperature is no more than 450° C. In some embodiments, the first temperature is no more than 400° C. In some embodiments, the molybdenum-containing precursor is a molybdenum oxyfluoride. In some embodiments, the method further includes partially filling the feature while the substrate is at the first temperature, and completely filling the feature (or filling a second portion of the feature) while the substrate is at a second temperature, the second temperature being greater than the first temperature. In some such embodiments, partially filling the feature takes place in a first station of a process chamber, and the completely filling the feature (or filling a second portion of the feature) takes place at a second station of the process chamber. In some embodiments, the metal-containing surface is one of a material from a group including cobalt, ruthenium, copper, tungsten, molybdenum, titanium, tin, tantalum, nickel, iridium, and rhodium. In some embodiments, the metal-containing surface is one of a material from a group including titanium nitride, molybdenum nitride, tungsten nitride, tungsten carbon nitride, titanium aluminum carbide, titanium silicide, and tantalum nitride. In some embodiments, the metal-containing surface is an elemental metal surface. In some embodiments, the sidewalls include an oxide. Examples of oxides include polyethyleneoxide, tetraethyl orthosilicate, flowable oxide, and a carbon doped oxide. In some embodiments, the Mo film on the metal-containing film has a larger thickness than the Mo film on the oxide or nitride surfaces of the sidewalls, such as at least about 20 Å greater than the Mo film on the oxide or nitride surfaces.

Another aspect of the disclosure relates to a method that includes: providing a substrate including a feature having a feature bottom and feature sidewalls, where the feature bottom includes a metal-containing surface and the feature sidewalls include oxide or nitride surfaces; and performing a deposition process to selectively deposit a molybdenum (Mo) film on the metal-containing surface relative to the oxide or nitride surfaces, where the deposition process includes exposing the feature to a molybdenum-containing oxyhalide precursor and a reducing agent at a first substrate temperature.

In some embodiments, the method also includes, prior to performing the deposition process, exposing the metal-containing surface to a hydrogen-containing plasma. In some embodiments, the metal-containing surface may be exposed to other treatments with examples including halogen-containing plasmas such as chlorine-(Cl-)based plasmas. In some embodiments, the reducing agent is thermal hydrogen (H₂). In some embodiments, the reducing agent is provided in a plasma generated from hydrogen (H₂). In some embodiments, the partial pressure of the reducing agent is at least 10 torr. In some embodiments, the molybdenum-containing precursor is a molybdenum oxychloride. In some embodiments, the first temperature is no more than 600° C. In some embodiments, the first temperature is no more than 450° C. In some embodiments, the first temperature is no more than 400° C. In some embodiments, the molybdenum-containing precursor is a molybdenum oxyfluoride. In some embodiments, the method further includes partially filling the feature while the substrate is at the first temperature, and completely filling the feature (or filling a second portion of the feature) while the substrate is at a second temperature, the second temperature being greater than the first temperature. In some such embodiments, partially filling the feature takes place in a first station of a process chamber, and the completely filling the feature (or filling a second portion of the feature) takes place at a second station of the process chamber. In some embodiments, the metal-containing surface is one of a material from a group including cobalt, ruthenium, copper, tungsten, molybdenum, titanium, tin, tantalum, nickel, iridium, and rhodium. In some embodiments, the metal-containing surface is one of a material from a group including titanium nitride, molybdenum nitride, tungsten nitride, tungsten carbon nitride, titanium aluminum carbide, titanium silicide, and tantalum nitride. In some embodiments, the metal-containing surface is an elemental metal surface. In some embodiments, the sidewalls include an oxide. Examples of oxides include polyethyleneoxide, tetraethyl orthosilicate, flowable oxide, and a carbon doped oxide. In some embodiments, the Mo film on the metal-containing film has a larger thickness than the Mo film on the oxide or nitride surfaces of the sidewalls.

These and further aspects are described below with reference to the drawings.

### BRIEF DESCRIPTION OF THE DRAWINGS

FIG. 1 shows an example of a molybdenum (Mo) interconnect according to various embodiments.

FIG. 2 shows examples of patterned features into which selective deposition of a Mo film may be performed according to various embodiments.

FIG. 3 shows an example of a selective deposition method to fill a feature with molybdenum according to various embodiments.

FIG. 4 and FIG. 5 show examples of cross-sectional schematic diagrams of a patterned feature after certain operations of methods according to certain embodiments of FIG. 3.

FIG. 6A shows an example of apparatus that include a gas manifold system and that may be employed according to various embodiments.

FIG. 6B shows an example of a method of selectively depositing a Mo layer by ALD according to various embodiments.

FIG. 7 is an image of Mo gapfill evolution in via structure with a landing on Cu. Image (a) shows selective partial Mo fill and image (b) shows full Mo fill without seams or voids.

FIG. 8 is a schematic diagram of an example process chamber for performing certain disclosed embodiments.

FIG. 9 is a schematic diagram of an example process tool for performing certain disclosed embodiments.

### DETAILED DESCRIPTION

Provided are methods of filling patterned features with molybdenum (Mo). The methods involve selective deposition of Mo films on bottom metal-containing surfaces of a feature including dielectric sidewalls. The selective growth of Mo on the bottom surface allows bottom-up growth and high quality, void-free fill.

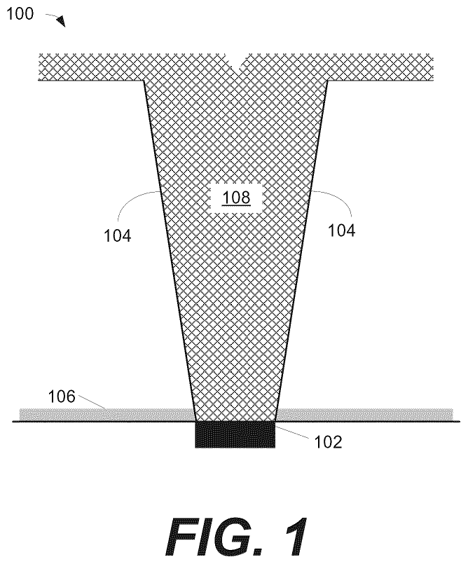

FIG. 1 depicts an example of a feature 100 according to various embodiments. The feature 100 includes a bottom surface 102 and one or more sidewall surfaces 104. An etch stop layer (ESL) 106 is also shown. The bottom surface 102 may be a metal-containing surface. The structure 100 is filled with molybdenum to form a Mo interconnect 108 that provides an electrical connection to the underlying contact.

In some embodiments, the bottom surface 102 is a metal-containing surface. The metal-containing surface may contain any appropriate metal, such as cobalt (Co), ruthenium (Ru), copper (Cu), tungsten (W), molybdenum (Mo), nickel (Ni), iridium (Ir), rhodium (Rh), tantalum (Ta), and titanium (Ti). In some embodiments, the metal-containing surface 102 is an elemental metal surface. There may be some oxide formed on the metal-containing surface due to exposure to moisture. In some embodiments, the metal-containing surface is a metal compound with examples including a titanium nitride (TiN), molybdenum nitride (MoNₓ), tungsten nitride (WN), tungsten carbon nitride (WCₓN_{y}), a titanium aluminum carbide (TiAlₓC_{y}), titanium silicide (TiSi₂), or tantalum nitride (TaN) surface. These surfaces may exhibit selectivity with respect to dielectric oxides.

As used herein, oxide surfaces include alkoxides such as tetraethyl orthosilicate (TEOS), fluorosilicate glass (FSG), flowable oxides, spin-on-glasses, carbon doped oxides, etc. In some embodiments, the oxide surface is a silicon-based oxide with examples given above.

The one or more sidewall surfaces 104 are dielectric surfaces. Such surfaces include alkoxides such as poly(2-ethyl-2-oxazoline) (PEOX) and silicon-based oxides including tetraethyl orthosilicate (TEOS) oxide, flowable silicon-based oxides, carbon doped silicon-based oxides, etc. These surfaces may be part of the main dielectric layer surrounding the feature. Selectivity refers to the preference in deposition on a metal surface, such as Co, W or Cu surface relative to a dielectric surface. It may be quantified as a ratio of deposition rates or as a ratio of deposition thicknesses after a certain number of deposition cycles.

In some embodiments, the sidewall surfaces may be nitrides (e.g., SiₓN_{y}) rather than oxides. The nitrides may be silicon-based nitrides or silicon-based oxynitrides. Selectivity of Mo film deposition on elemental metal with respect to nitrides is similar to that with respect to oxides.

The Mo interconnect 108 may be part of any appropriate part of a partially fabricated semiconductor device, including a source/drain (S/D) connection, a middle of the line (MOL) structure or an back end of line (BEOL) structure.

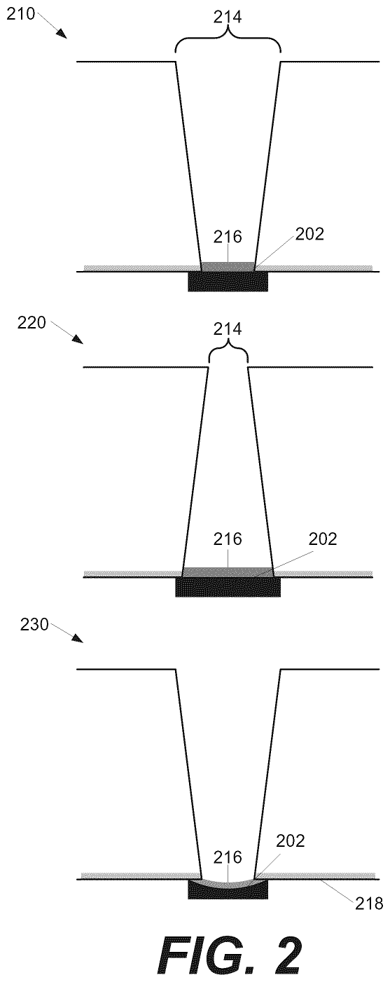

FIG. 2 shows example embodiments of patterned features in which selective deposition of a Mo film may be performed. A patterned feature may be a via or a trench or other appropriate feature formed as a result of a patterning operation in a dielectric layer. Feature 210 shows an example of a patterned feature having an open profile that expands gradually from the bottom of the feature to the feature opening 214.

Feature 220 shows an example of a patterned feature having a re-entrant profile that narrows from the bottom of the feature to the feature opening 214. A re-entrant profile may also include an overhang at the feature opening 214. Feature 230 shows a feature with a metal undercut profile. According to various implementations, the profile has the metal-containing surface below the sidewall base 218 of the feature 230. There may be voids between the bottom surface 202 and the sidewall base 218. In each of the above profiles, the bottom surface 202 may be a metal containing-surface. There may be metal-oxide 216 formed on bottom surface 202.

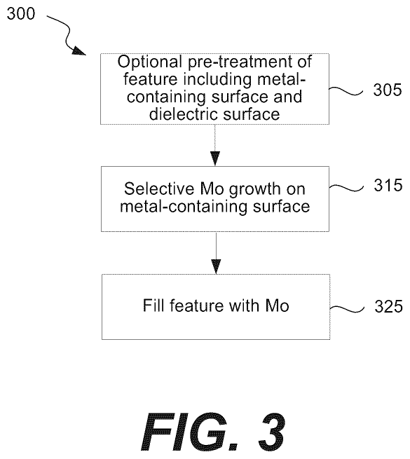

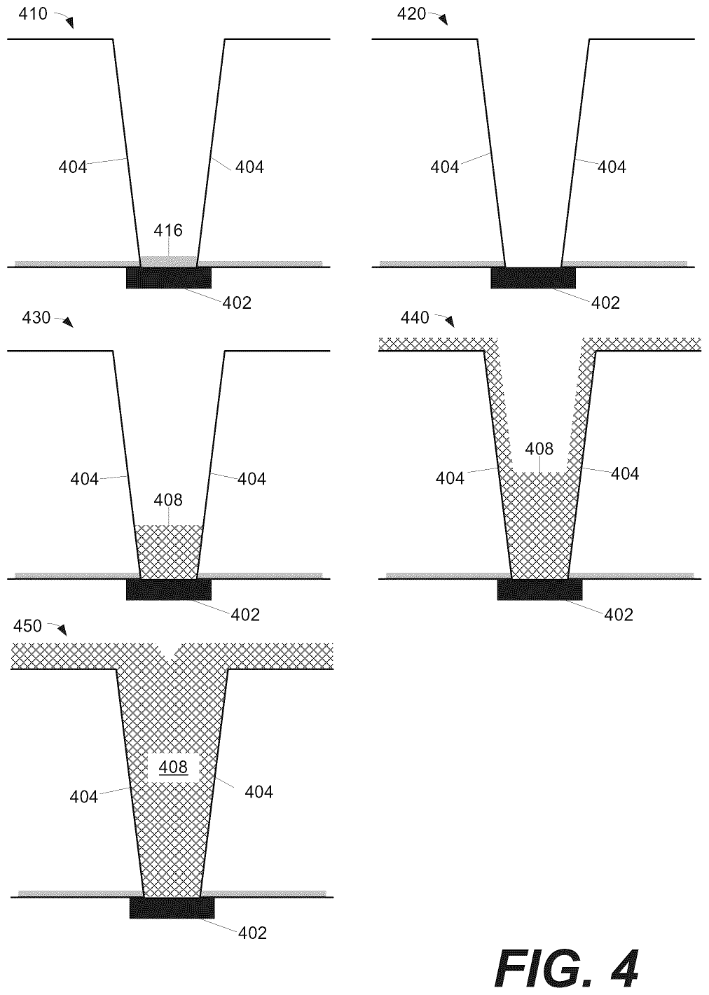

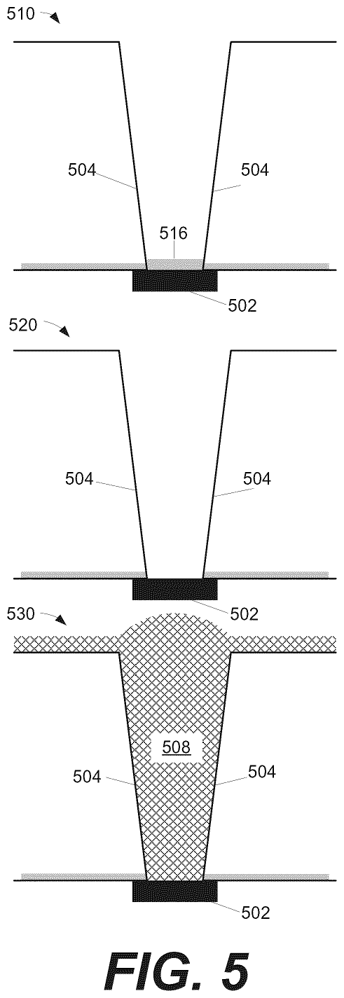

FIG. 3 is a flow diagram showing an example of a selective deposition method 300 to fill a feature with a Mo film. FIG. 4 and FIG. 5 show examples of cross-sectional schematic diagrams of a patterned feature after certain operations of embodiments of the method of FIG. 3. In particular, FIG. 4, at 410, a patterned feature is shown prior to application of the selective deposition method 300. The patterned feature may be, for example, an etched feature. The patterned feature includes bottom surface 402 and sidewall surfaces 404, which may be oxide or nitride. In some embodiments, there may be a metal-oxide 416 on the bottom surface 402.

In FIG. 3, at operation 305, an optional pre-treatment of a feature including a metal-containing surface and a dielectric surface is performed. A pre-treatment may be used to reduce any metal-oxide on the metal-containing surface and thus may include exposing the feature to a reducing agent such as hydrogen species. Pre-treatment of the feature may include exposing the feature to a hydrogen-containing plasma. In some embodiments the hydrogen-containing plasma was generated from hydrogen gas (H₂). For some surfaces, an H₂-based plasma may not be effective to reduce metal-oxide or otherwise prepare the surface. In such cases, other treatments may be used. In one example, a halogen-based plasma may be used to treat a silicide surface such as a TiSi₂ surface. Examples include plasmas generated from chlorine (Cl₂) and/or boron trichloride (BCl₃).

The pre-treatment, if performed, may be a plasma treatment or, in some embodiments, a thermal treatment. Thermal treatments can involve exposing the surface to a gas in a non-plasma environment. In one example, a hydrogen fluoride (HF) may be used to treat metal silicides such as TiSi₂ and other metal compound or metal surfaces. If a plasma treatment is performed, it may be a remote plasma or an in situ plasma. An in situ plasma refers to a plasma that is generated in a chamber that houses the substrate, generally without a filter interposed between the substrate and the generated plasma, and may include ions and radicals. A remote plasma refers to a plasma that is generated remotely from the substrate. It may be generated in a dome or other space that is part of or connected to the chamber the substrate is in or in a separate, self-contained unit. A showerhead or other filter is generally interposed between the generator and the substrate. In some embodiments, a remote plasma contains only radicals or other neutral species, with no ions. In FIG. 4, at 420 is an embodiment of feature 410 after operation 305 is performed. In this embodiment, the metal-containing surface 402 no longer has metal-oxide.

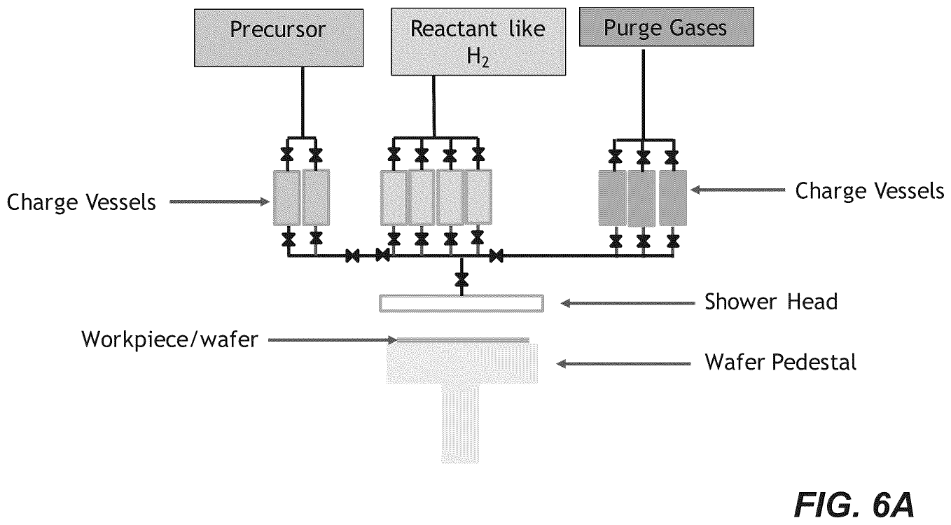

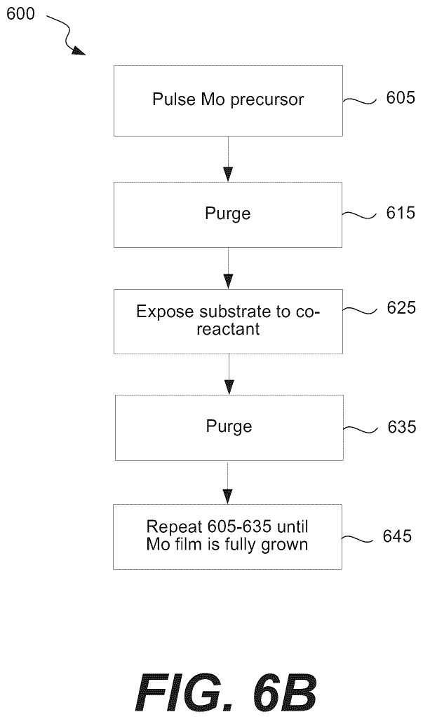

Returning to FIG. 315, at block 315, selective growth of the Mo film is performed on the metal-containing surface. Selective deposition refers to deposition that is selective to the metal-containing surface with respect to the oxide or nitride surfaces. As such, the portion of the fill that is formed on the metal-containing surface is thicker than that formed on the oxide or nitride surfaces. This is shown in FIG. 4, at 430, which shows the start of the selective deposition of a Mo film 408. The Mo film 408 nucleation starts on the metal-containing bottom surface 402. In the example of FIG. 4, there is no growth of Mo film on the oxide or nitride of the sidewall surfaces 404. The growth on the metal-containing bottom surface 402 may result in larger grain sizes and/or reduced resistance. Selective deposition may be used during ALD (as described in further below with respect to FIG. 6) or chemical vapor deposition (CVD).

To deposit Mo selectively, Mo precursors, temperature, and reactant partial pressure may be controlled. The Mo precursors are oxyhalides, such as MoxOxHz and His a halogen (fluorine (F), chlorine (Cl), bromine (Br), or iodine (I)) and x, y, and z being any number greater than zero that can form a stable molecule. Examples of Mo precursors are molybdenum tetrafluoride oxide (MoOF₄), molybdenum tetrachloride oxide (MoOCl₄), molybdenum dichloride dioxide (MoO₂Cl₂), molybdenum dibromide dioxide (MoO₂Br₂), and molybdenum oxyiodides MoO₂I and Mo₄O₁₁I. A reducing agent reacts with the molybdenum oxyhalide to form elemental molybdenum. In some embodiments, the reducing agent is thermal or plasma hydrogen (H₂).

Temperature affects selectivity, grain size, and resistance. Higher temperatures may reduce selectivity of the Mo film and result in growth on the oxide or nitride of the sidewall surfaces 404 as well as on the metal-containing bottom surface 402. However, if temperatures are too low, the impurity level may be increased and grain size may be reduced, increasing resistance. Substrate temperature may be between 350° C. and 600° C., inclusive, to selectively deposit Mo using a chlorine-containing chemistry. As noted above, selectivity can improve as temperature is lowered. Thus, in some embodiments, substrate temperature may be between about 350° C. and 550° C., or 350° C. and 450° C. for a chlorine-containing precursor. Substrate temperatures for a fluorine-containing chemistry may be lower, e.g., 150° C. to 350° C.

At block 325 of FIG. 3, the feature is filled with Mo. A start of the Mo fill process is shown at 430 of FIG. 4. The Mo film 408 may continue to grow on the metal-containing surface 402. At 404, the Mo film may also start to nucleate on the oxide or nitride of the sidewall surfaces 404. The Mo film 408 fills the feature and has a larger thickness from the metal-containing bottom surface 402 than the Mo film 408 grown from the sidewall 404.

In some embodiments, a multi-stage Mo deposition is performed. In FIG. 4, an initial stage is represented at 430 and 440 in which selective deposition is performed. A second stage is represented at 450 in which deposition conditions are changed to increase deposition rate and throughput. At 450, conformal growth (rather than bottom-up, non-conformal growth) occurs. By raising the substrate temperature, the growth rate of the Mo film 408 increases from both the bottom and the sidewall, reducing the time to fill the feature. In the example of FIG. 4, the temperature is raised after some amount of film is nucleated on the sidewall surface. In other embodiments, there may not be any Mo nucleated on some or all of the sidewall surfaces above the portion of the film grown from the bottom-up. Raising the temperature can allow nucleation on these sidewall surfaces. This may be appropriate once the feature has filled sufficiently such that conformal growth can be used to obtain good feature fill without a risk of voids. The temperature may be raised at least 50° C., at least 100° C., or at least 150° C., and may be at least 500° C. and as high as 800° C. as long as the thermal budget is allowed in the device structure.

In some embodiments, the substrate temperature or other process parameters are not changed to increase deposition rate, with the feature filled at the selective deposition conditions. This is illustrated in FIG. 5; at 510, a feature having sidewall surfaces 504 and a bottom surface 502 is shown. A metal-oxide 516 is on the bottom surface 502. At 520, the feature is shown after the metal-oxide is removed. And, at 530, the feature is shown after Mo deposition fills the feature. In a single stage deposition, without a change in process conditions, deposition may remain selective, with bottom-up fill used to fill the feature, or may transition from selective deposition to a more conformal deposition as some Mo begins to nucleate on the sidewalls, reducing the selectivity.

Deposition of pure metal films from oxygen-containing precursors is challenging due to the ease of incorporation of oxygen into the films during the deposition process. If oxygen is incorporated, the resistivity increases. The methods and apparatus described herein may be implemented to deposition pure metal films that have less than 1 atomic percent oxygen in some embodiments. The ratio of the reducing agent to the metal oxy-halide precursor is significantly greater than 1 and the deposited film contains no more than 1 atomic percentage oxygen. Molar ratios of at least 100:1 may be used. In some embodiments, the deposited film has a halogen concentration of no more than 1E18 atoms/cm³. To deposit pure films with no more than one atomic percentage oxygen, the reducing agent to metal precursor ratio is significantly greater than 1, e.g., at least 20:1 or at least 50:1. Examples of temperatures may ranges from 350° C. to 600° C. for chlorine-containing precursors and 150° C. to 500° C. for fluorine-containing precursors. Examples of chamber pressures may range from 1 torr to 100 torr. The reducing agent: precursor ratio used to obtain pure films may be lower as temperature is increased. In some embodiments, the temperature for chlorine-containing precursors is at least 400° C. Higher pressures may also be used to reduce the reducing agent: precursor ratio as the partial pressure of the reducing agent is increased.

For processes such as ALD that employ pulses, the number of reducing agent pulses may be greater than the number of precursor pulses in some embodiments. The methods may be implemented using multiple charging vessels. An example apparatus is shown schematically in FIG. 6A, in which the 3 gas sources (precursor, H₂, and purge gases) are connected to charge vessels. The apparatus includes a gas manifold system, which provides line charges to the various gas distribution lines. The manifolds provide the precursor gas, reducing gas and purge gas to the deposition chamber through valved charged vessels. The various valves are opened or closed to provide a line charge, i.e., to pressurize the distribution lines. In various embodiments, the number (a total charge volume) of reducing agent charge vessels may be greater than the number of precursor and/or purge gas charge vessels. Multiple pulses of reducing agent for every one pulse of precursor allows for fast reduction of the oxygen containing precursor to deposit the high purity, low resistivity metal film. In some embodiments, multiple charge vessels may be used for the precursor as well as the reducing agent. This allows multiple pulses to be introduced and enables complete reduction of the oxygen-containing precursors.

The ratio of reducing agent to precursor may be characterized as the ratio of molecules that the substrate is exposed to and are available to react. It may be calculated from:

$$\frac{\begin{matrix}Reducing agent flow rate \times \\ ( Reducing agent line charge time + Reducing agent dose time )\end{matrix}}{\begin{matrix}Precursor flow rate \times \\ ( Precursor line charge time + Precursor dose time )\end{matrix}}$$

Line charges are pressurized distributions. Dose time refers to the amount of time the dose (also referred to a pulse) lasts. This may be simplified to the below where there is no line charge time:

$$\frac{Reducing agent flow rate \times Reducing agent dose time}{Precursor flow rate \times Precursor dose time}$$

The above expressions are molar ratios, with example molar ratios ranging from 50:1 to 10000:1, 50:1 to 2000:1, 100:1 to 10000:1, or 100:1 to 2000:1.

The ratio of reducing agent to precursor may be characterized as a volumetric ratio, which may be calculated as

$$\frac{Reducing flow rate at showerhead}{Precursor flow rate at showerhead}$$

The volumetric ratio may be 50:1 to 2000:1, for example.

In some embodiments, an ALD method is used to selectively deposit Mo. FIG. 6B is flow diagram showing operations in an ALD method. At 605, a Mo precursor is pulsed. As discussed above, the Mo precursor is molybdenum-containing oxyhalide precursor, which is adsorbed onto the substrate. After the Mo precursor is pulsed, an optional purge 615 may occur. Argon or any inert gas may be used to purge the chamber of any unadsorbed precursor. The substrate is exposed to a co-reactant 625, which is a reducing agent to reduce the Mo precursor. The reactant may be a hydrogen-containing reactant. In some embodiments, the hydrogen-containing reactant may be thermal hydrogen (H₂). A remote or in-situ plasma generated from H₂. For thermal (non-plasma) processes, the partial pressure of the co-reactant may be controlled to tune selectivity, with partial pressure at least 10 Torr. Low reactant partial pressure increases the selectivity due to the increase in nucleation delay on dielectrics. Higher pressures may be used with shorter exposure times and lower pressures may be used with longer exposure times. An optional purge may be performed at 635, followed by repeating operations 605-635 until the film is fully grown. As discussed above, this may involve filling the feature completely, and can involve raising the temperature appropriately to move to higher deposition rate process after the film is sufficiently grown from the bottom.

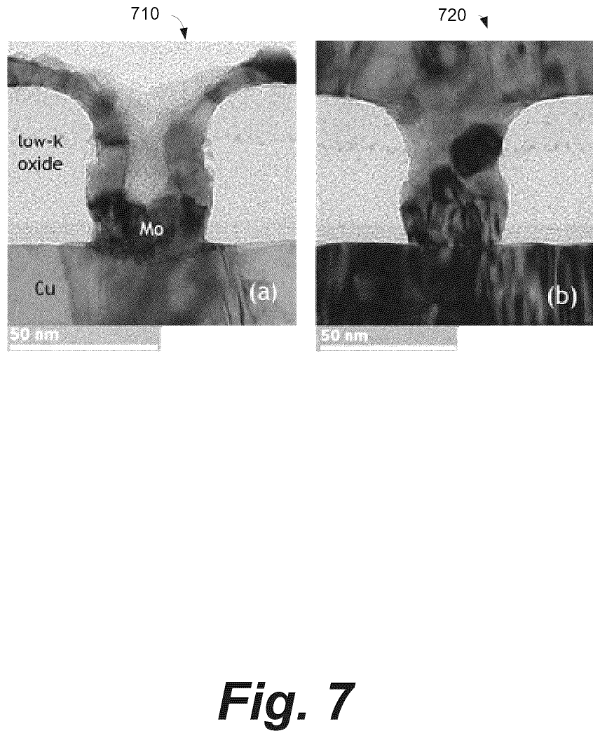

FIG. 7 shows transmission electron microscope (TEM) images that shows the results of selective ALD deposition using MoO₂Cl₂ at 400° C. Image 710 shows Mo selectively deposited on a Cu surface relate to the oxide sidewalls and image 720 shows the resulting good gapfill.

### APPARATUS

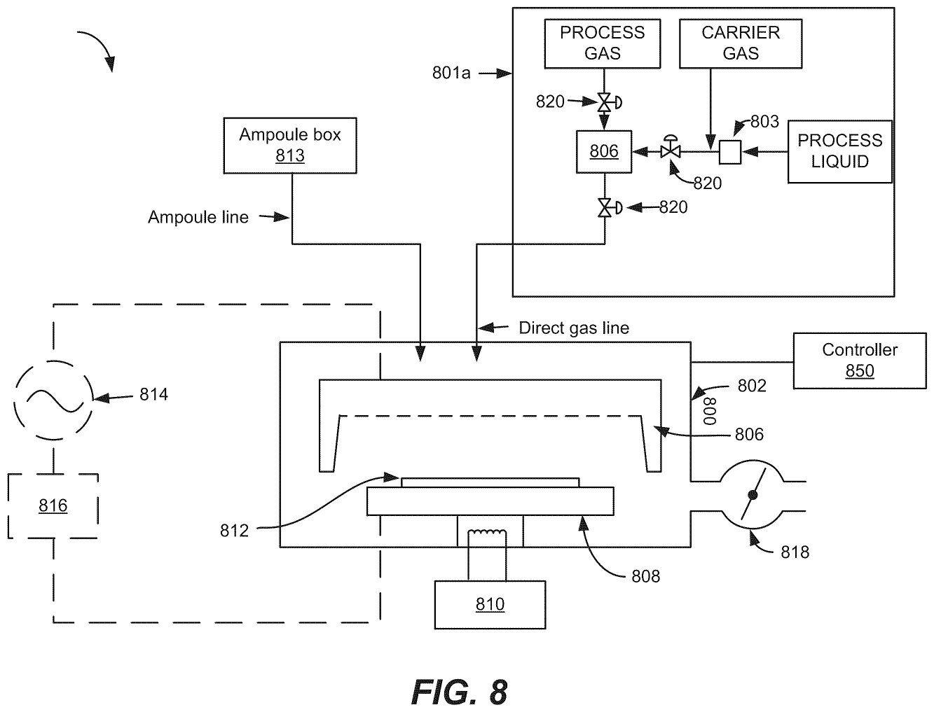

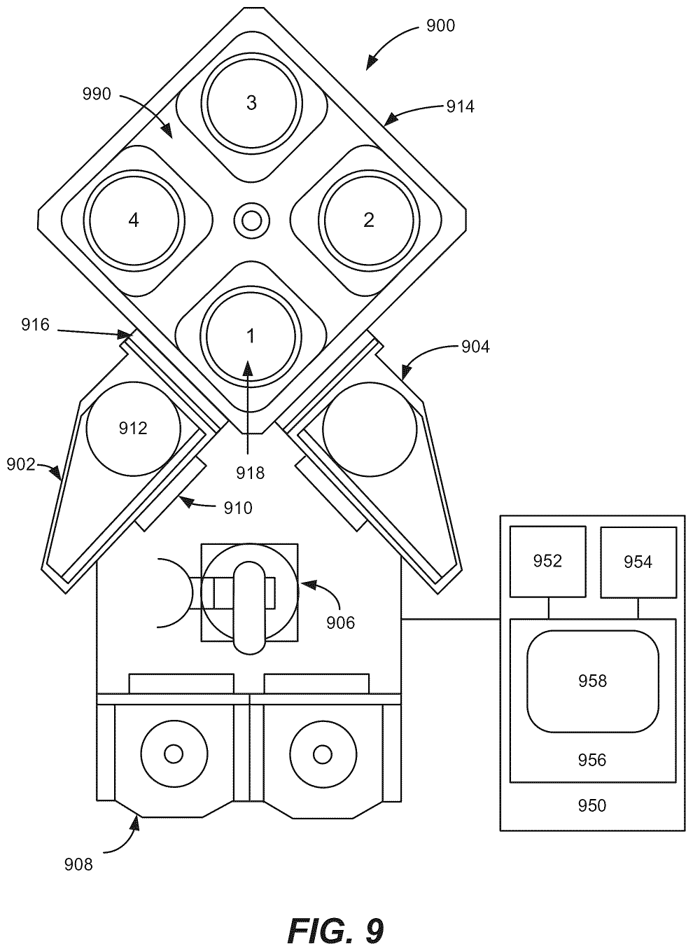

FIG. 8 depicts a schematic illustration of an embodiment of an ALD process station 800 having a process chamber 802 for maintaining a low-pressure environment. A plurality of ALD process stations may be included in a common low pressure process tool environment. For example, FIG. 9 depicts an embodiment of a multi-station processing tool 900. In some embodiments, one or more hardware parameters of ALD process station 800, including those discussed in detail below, may be adjusted programmatically by one or more computer controllers 850.

ALD process station 800 fluidly communicates with reactant delivery system 801a for delivering process gases to a distribution showerhead 806. Reactant delivery system 801a includes a mixing vessel 804 for blending and/or conditioning process gases, such as a Mo precursor-containing gas or hydrogen-containing gas for delivery to showerhead 806. One or more mixing vessel inlet valves 820 may control introduction of process gases to mixing vessel 804. In various embodiments, selective deposition of a Mo film is performed in process station 800 and in some embodiments, other operations such as pre-treatment may be performed in the same or another station of the multi-station processing tool 900 as further described below with respect to FIG. 9.

As an example, the embodiment of FIG. 8 includes a vaporization point 803 for vaporizing liquid reactant to be supplied to the mixing vessel 804. In some embodiments, vaporization point 803 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 804. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 806.

In some embodiments, a liquid flow controller (LFC) upstream of vaporization point 803 may be provided for controlling a mass flow of liquid for vaporization and delivery to process chamber 802. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 806 distributes process gases toward substrate 812. In the embodiment shown in FIG. 8, the substrate 812 is located beneath showerhead 806 and is shown resting on a pedestal 808. Showerhead 806 may have any suitable shape, and may have any suitable number and arrangement of ports for distributing process gases to substrate 812.

In some embodiments, pedestal 808 may be raised or lowered to expose substrate 812 to a volume between the substrate 812 and the showerhead 806. In some embodiments, pedestal 808 may be temperature controlled via heater 810. Pedestal 808 may be set to any suitable temperature, such as between about 350° C. and about 450° C. during operations for performing various disclosed embodiments. It will be appreciated that, in some embodiments, pedestal height may be adjusted programmatically by a suitable computer controller 850. At the conclusion of a process phase, pedestal 808 may be lowered during another substrate transfer phase to allow removal of substrate 812 from pedestal 808.

In some embodiments, a position of showerhead 806 may be adjusted relative to pedestal 808 to vary a volume between the substrate 812 and the showerhead 806. Further, it will be appreciated that a vertical position of pedestal 808 and/or showerhead 806 may be varied by any suitable mechanism within the scope of the present disclosure. In some embodiments, pedestal 808 may include a rotational axis for rotating an orientation of substrate 812. It will be appreciated that, in some embodiments, one or more of these example adjustments may be performed programmatically by one or more suitable computer controllers 850. The computer controller 850 may include any of the features described below with respect to controller 950 of FIG. 9.

In some embodiments where plasma may be used as discussed above, showerhead 806 and pedestal 808 electrically communicate with a radio frequency (RF) power supply 814 and matching network 816 for powering a plasma. In some embodiments, the plasma energy may be controlled by controlling one or more of a process station pressure, a gas concentration, an RF source power, an RF source frequency, and a plasma power pulse timing. For example, RF power supply 814 and matching network 816 may be operated at any suitable power to form a plasma having a desired composition of radical species. Likewise, RF power supply 814 may provide RF power of any suitable frequency. In some embodiments, RF power supply 814 may be configured to control high-and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 850 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor such as a Mo precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 800 may be provided by butterfly valve 818. As shown in the embodiment of FIG. 8, butterfly valve 818 throttles a vacuum provided by a downstream vacuum pump (not shown). However, in some embodiments, pressure control of process station 800 may also be adjusted by varying a flow rate of one or more gases introduced to the process station 800.

As described above, one or more process stations may be included in a multi-station processing tool. FIG. 9 shows a schematic view of an embodiment of a multi-station processing tool 900 with an inbound load lock 902 and an outbound load lock 904, either or both of which may include a remote plasma source (not shown). A robot 906, at atmospheric pressure, is configured to move wafers from a cassette loaded through a pod 908 into inbound load lock 902 via an atmospheric port 910. A wafer (not shown) is placed by the robot 906 on a pedestal 912 in the inbound load lock 902, the atmospheric port 910 is closed, and the load lock inbound 902 is pumped down. Where the inbound load lock 902 includes a remote plasma source, the wafer may be exposed to a remote plasma treatment in the inbound load lock 902 prior to being introduced into a processing chamber 914. Further, the wafer also may be heated in the inbound load lock 902 as well, for example, to remove moisture and adsorbed gases. Next, a chamber transport port 916 to processing chamber 914 is opened, and another robot (not shown) places the wafer into the reactor on a pedestal of a first station shown in the reactor for processing. While the embodiment depicted in FIG. 9 includes load locks, it will be appreciated that, in some embodiments, direct entry of a wafer into a process station may be provided.

The depicted processing chamber 914 includes four process stations, numbered from 1 to 8 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an ALD and plasma-enhanced ALD process mode. In some embodiments, exposure to a deposition precursor and exposure to a second reactant and plasma are performed in the same station. Additionally or alternatively, in some embodiments, processing chamber 914 may include one or more matched pairs of ALD and plasma-enhanced ALD process stations. Further, exposure to a pre-treatment gas or plasma and an ALD process may occur in the same or different stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations. Still further, in some embodiments, partial gap fill may be performed at first station at a first pedestal temperature with the substrate moved to a second station at a second pedestal temperature.

FIG. 9 depicts an embodiment of a wafer handling system 990 for transferring wafers within processing chamber 914. In some embodiments, wafer handling system 990 may transfer wafers between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog, and/or digital input/output connections, stepper motor controller boards, etc.

In some embodiments, system controller 950 controls all of the activities of process tool 900. System controller 950 executes system control software 958 stored in mass storage device 954, loaded into memory device 956, and executed on processor 952. Alternatively, the control logic may be hard coded in the controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, gas flow rates, chamber and/or station pressure, chamber and/or station temperature, plasma exposure duration, UV radiation duration, wafer temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

In some embodiments, system control software 958 may include input/output control (IOC) sequencing instructions for controlling the various parameters described above. Other computer software and/or programs stored on mass storage device 954 and/or memory device 956 associated with system controller 950 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 918 and to control the spacing between the substrate and other parts of process tool 900.

A process gas control program may include code for controlling gas composition (e.g., organo-tungsten compound-containing gases, co-reactant gases, gases for performing a pre-treatment, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 950. The user interface may include a display screen, graphical software displays of the apparatus and/or process conditions, and user input devices such as pointing devices, keyboards, touch screens, microphones, etc.

In some embodiments, parameters adjusted by system controller 950 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 950 from various process tool sensors. The signals for controlling the process may be output on the analog and digital output connections of process tool 900. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 950 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 950 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 950.

In some implementations, the system controller 950 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 950, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 950 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 950 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 950, in some implementations, may be a part of or coupled to a computer that is integrated with, coupled to the system, otherwise networked to the system, or a combination thereof. For example, the system controller 950 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 950 receives instructions in the form of data, which specify parameters for each of the processing steps to be performed during one or more operations. It should be understood that the parameters may be specific to the type of process to be performed and the type of tool that the system controller 950 is configured to interface with or control. Thus as described above, the system controller 950 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

While FIGS. 8 and 9 provide examples of chambers and tools that may be used to perform the methods disclosed herein, various modifications may be made. These include the use of any CCP or ICP plasma generator or the use of a remote plasma generator.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 950 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1-19. (canceled)

20. A method comprising:
providing a substrate comprising a feature having a feature bottom and feature sidewalls, wherein the feature bottom comprises a metal or metal nitride surface and the feature sidewalls comprise oxide surfaces; and
performing multiple cycles of an atomic layer deposition (ALD) process to selectively deposit a molybdenum (Mo) film on the metal or metal nitride surface relative to the oxide surfaces, wherein the ALD process comprises exposing the feature to alternate pulses of molybdenum-containing precursor and a reducing agent at a first temperature.

21. The method of claim 20, further comprising, prior to performing the multiple cycles of the ALD deposition process, exposing the metal-containing surface to a hydrogen-containing plasma.

22. The method of claim 20, wherein the reducing agent is thermal hydrogen (H₂).

23. The method of claim 20, wherein the reducing agent is provided in a plasma generated from hydrogen (H₂).

24. The method of claim 20, wherein the partial pressure of the reducing agent is at least 10 Torr.

25. The method of claim 20, wherein the molybdenum-containing precursor is a chlorine-containing.

26. The method of claim 20, wherein the first temperature is no more than 600° C.

27. The method of claim 20, wherein the first temperature is no more than 450° C.

28. The method of claim 20, wherein the first temperature is no more than 400° C.

29. The method of claim 20, wherein the first temperature is at least 350° C.

30. The method of claim 20, wherein the molybdenum-containing precursor is a fluorine-containing.

31. The method of claim 20, further comprising filling the feature at a higher temperature than the first temperature.

32. The method of claim 31, wherein filling the feature comprises growing molybdenum on the oxide surfaces.

33. The method of claim 32, wherein the molybdenum is grown non-selectively on the oxide and metal or metal nitride surfaces.

34. The method of claim 20, further comprising, partially filling the feature while the substrate is at the first temperature and completely filling the feature while the substrate is at a second temperature, the second temperature being greater than the first temperature.

35. The method of claim 35, wherein the partial filling takes place in a first station of a process chamber and the complete filling takes place at a second station of the process chamber.

36. The method of claim 20, wherein the metal or metal nitride surface is one of:
cobalt, ruthenium, copper, tungsten, molybdenum, titanium, tin, tantalum, nickel, iridium, and rhodium.

37. The method of claim 20, wherein the metal or metal nitride surface is one of:
titanium nitride, molybdenum nitride, tungsten nitride, tungsten carbon nitride, titanium silicide, and tantalum nitride.

38. The method of claim 20, wherein the metal or metal nitride surface is an elemental metal surface.

39. The method of claim 20, wherein the sidewalls comprise an oxide is selected form:
polyethyleneoxide, tetraethyl orthosilicate, flowable oxide, and a carbon doped oxide.
